(19) United States
(12) Patent Application Publication
(10) Pub. No.: US 2008/0303147 A1
(43) Pub. Date: Dec. 11, 2008

(54) HIGH-FREQUENCY CIRCUIT DEVICE AND RADAR

(75) Inventors: Hiromichi WATANABE, Hyogo (JP); Takashi YONEMOTO, Hyogo (JP); Shinichi SUGIURA, Hyogo (JP)

Correspondence Address: OLIFF & BERRIDGE, PLC, P.O. BOX 320850, ALEXANDRIA, VA, 22320-4850, US

(73) Assignee: FUJITSU TEN LIMITED, KOBE-SHI (JP)

(21) Appl. No.: 12/133,916

(22) Filed: Jun. 5, 2008

(30) Foreign Application Priority Data
Jun. 5, 2007 (JP) 2007-148989

(51) Int. Cl. H01L 23/488

(52) U.S. Cl. 257/737; 257/E23.023

(57) ABSTRACT

A semiconductor chip is provided with a high-frequency circuit. A multi-layer wiring section is comprised of organic material and formed on the semiconductor chip, an outermost layer of the multi-layer wiring section formed with a bump forming portion. A bump is formed on the bump forming portion. The multi-layer wiring section is provided with a reinforcing means for suppressing a deformation of a bonding portion between the bump and the bump forming portion when the high-frequency circuit device is bonded to a substrate with an ultrasonic vibration applied thereto.

Priority is claimed to Japanese Patent Application No. 2007-148989 filed on Jun. 5, 2007, the disclosure of which, including the specification, drawings and claims, is incorporated herein by reference in its entirety.

### BACKGROUND

The present invention relates to a high-frequency circuit device and a radar, and more particularly, to a high-frequency circuit device that can be mounted on a radar using electromagnetic waves of bands of microwaves or millimeter waves and a radar.

In recent years, a system supporting the driving safety of a vehicle, for example, an adaptive cruise control (ACC) system controlling an inter-vehicle distance from a previously traveling vehicle or a free-crash brake system winding up a safety belt and braking a vehicle when a collision cannot be avoided, was in the course of development.

A vehicle mounted with such a driving safety supporting system is mounted with a radar (for example, millimeter-wave radar) for detecting an inter-vehicle distance from a previously traveling vehicle. The vehicle millimeter-wave radar includes an antenna unit, a millimeter-wave transceiver, an analog circuit unit, a digital signal processor, and an external interface. A variety of radars such as an FM-CW radar, a 2-frequency CW radar, a pulse radar, and a spread spectrum radar have been developed.

Among the components of the millimeter-wave radar, the millimeter-wave transceiver is a particularly important one. Recently, a monolithic microwave integrated circuit (MMIC) was employed as a component of the millimeter-wave transceiver.

In the past, the MMIC has a ceramic package structure in which the MMIC is mounted on a ceramic substrate and is sealed with a cap. However, the ceramic substrate and the cap which are essential to the MMIC were expensive, thereby causing an enhancement in cost for components cost.

Therefore, in order to accomplish the simplification in structure or the decrease in cost of the millimeter-wave transceiver, the inventors tried to develop a high-frequency circuit device having a structure in which a multi-layer wiring section is formed on one surface (electrode forming surface) of a small-sized MMIC chip out of polyimide resin for airtight sealing and plural minute gold bumps are formed on the outermost layer of the multi-layer wiring section, instead of the ceramic package structure.

In such a high-frequency circuit device, since the multi-layer wiring section formed on the electrode forming surface of the MMIC chip includes thin-film layers formed of the polyimide resin, an ultrasonic bonding method of applying a pressure (weight) and a vibration (ultrasonic vibration) at the normal temperature (to 125° C.) instead of heat and pressure is employed as a mounting method onto an external substrate.

FIG. 1(a) is a partially enlarged sectional view schematically illustrating a part of a known high-frequency circuit device and FIG. 1(b) is a partially enlarged sectional view schematically illustrating a part of the high-frequency circuit device which has been mounted on an external substrate by an ultrasonic bonding method.

In the figure, reference numeral 1 represents a high-frequency circuit device. The high-frequency circuit device 1 includes a small-sized MMIC chip 2 having a substantially rectangular parallelepiped shape having horizontal and vertical lengths of about several millimeters, a multi-layer wiring section 3 formed on an electrode forming surface 2a of the MMIC chip 2, and bumps 6 formed on the outermost layer of the multi-layer wiring section 3.

The multi-layer wiring section 3 includes plural thin-film layers 3a to 3e stacked out of a polyimide resin material, a bump forming portion 4 formed by exposing a bump base conductive layer 5a from the outermost thin-film layer 3a, a conductive pattern 5b drawn from the bump base conductive layer 5a of the bump forming portion 4, and a via hole 5c having one end connected to the conductive pattern 5b and the other end connected to an electrode of the MMIC chip 2.

The bump forming portion 4 is formed by coating a portion other than the bump forming portion 4 in the outermost layer (thin-film layer 3a) of the multi-layer wiring section 3 with a resist film and processing the portion by the use of an etchant to etch the bump forming portion 4 of the thin-film layer 3a. However, since the size of the bump 6 to be formed is small, as shown in FIG. 1(a), in the bump forming portion 4 before being mounted on an external substrate 20, a section of the thin-film layer 3a is depressed in a rounded mortar shape and the bump 6 is formed to cover the depressed portion 3a′.

In the figure, reference numeral 20 represents the external substrate made of resin on which the high-frequency circuit device 1 is mounted. A pad 21 to be bonded to the bump 6 of the high-frequency circuit device 1 is formed at a predetermined position of the external substrate 20.

By setting an output level of the ultrasonic vibration so as to obtain a sufficient bonding strength to the external substrate 20 and performing the ultrasonic bonding process, as shown in FIG. 1(b), the bump 6 is pressed and crushed to a certain thickness and the depressed portion 3a′ of the thin-film layer 3a is pushed into the bump base conductive layer 5a by means of the pressing force resulting from the pushing of the bump 6.

When the depressed portion 3a′ is pushed into the bump base conductive layer 5a, the pushed portion of the bump base conductive layer 5a is pushed out externally and thus the thickness of the bump base conductive layer 5a is locally reduced, thereby causing a disconnection in the conductive pattern 5b.

In this way, by setting the output level of the ultrasonic vibration so as to obtain the sufficient bonding strength to the external substrate 20, the above-mentioned problem is caused. Accordingly, in the past, the bonding should be performed necessarily in a state where the output level of the ultrasonic vibration was reduced to a certain extent.

However, when the bonding is performed with a reduced output level of the ultrasonic vibration, a phenomenon that a peeling is caused in the bonding portion to the external substrate 20 may be generated, thereby making it difficult to sufficiently secure the bonding strength to the external substrate 20. In order to perform the strong bonding with the reduced output level of the ultrasonic vibration, it is necessary to enhance the degree of clearness of the bonding surface or to enhance the required level of plane precision of the bonding portion. Accordingly, there is a problem in that the management cost for components in the manufacturing process increases and the yield of the manufactured components decreases.

Techniques for reducing in size or cost of the millimeter transceiver were also disclosed (for example, see Patent Documents 1 and 2). The patent documents disclose devices in which an MMIC chip is mounted on a multi-layer substrate (external substrate) in which wires are stereoscopically formed, but do not particularly disclose the structure of the multi-layer wiring layer formed on the MMIC chip. By studying the structure of the multi-layer wiring layer formed in the MMIC chip, it can be considered that it is possible to enhance the reliability of the connection between the MMIC chip and the external substrate and to decrease the size of the radar device. However, no patent document specifically describes the problem with disconnection generated in the multi-layer wiring layer formed in the MMIC chip due to the ultrasonic bonding process and the problem has not been reviewed sufficiently.

Patent Document 1: Japanese Patent No. 3129288

Patent Document 2: Japanese Patent Publication No. 2003-332517A

### SUMMARY

It is therefore an object of at least one embodiment of the present invention to provide a high-frequency circuit device that can prevent a disconnection of a conductor portion of a multi-layer wiring section formed on a semiconductor chip even when an ultrasonic bonding process is performed by setting the output level of an ultrasonic vibration so as to obtain a sufficient bonding strength and that can reduce the management cost for components in a manufacturing process thereof or enhance the yield of manufactured components.

In order to achieve the above-described object, according to a first aspect of at least one embodiment of the present invention, there is provided a high-frequency circuit device comprising: a semiconductor chip provided with a high-frequency circuit; a multi-layer wiring section comprised of organic material and formed on the semiconductor chip, an outermost layer of the multi-layer wiring section formed with a bump forming portion; and a bump formed on the bump forming portion; wherein the multi-layer wiring section is provided with a reinforcing means for suppressing a deformation of a bonding portion between the bump and the bump forming portion when the high-frequency circuit device is bonded to a substrate with an ultrasonic vibration applied thereto.

With the above configuration, when the high-frequency circuit device is bonded to the substrate with the ultrasonic vibration applied thereto, it is possible to suppress the deformation of the bonding portion between the bump and the bump forming portion and to prevent a disconnection from being generated in the wire (conductive pattern or via hole) drawn from the bump forming portion. The bonding portion between the bump and the bump forming portion includes not only a portion to which the bump is directly bonded but also a region around the bonding portion.

Since the output level of the ultrasonic vibration can be set to perform an ultrasonic bonding process without markedly lowering the output level of the ultrasonic vibration, that is, so as to obtain a satisfactory bonding strength, it is possible to accomplish the strong bonding to the substrate. Since it is also possible to lower the allowable level of the clearness of the bonding surface or the required level of the plane precision, it is possible to reduce the management cost for components in the manufacturing process and to enhance the yield of the manufactured components, thereby enhancing the cost reducing effect.

According to a second aspect of at least one embodiment of the present invention, there is provided a high-frequency circuit device comprising: a semiconductor chip provided with a high-frequency circuit; a multi-layer wiring section comprised of organic material and formed on the semiconductor chip, an outermost layer of the multi-layer wiring section formed with a bump forming portion; a bump formed on the bump forming portion; and a wire electrically connecting the semiconductor chip with the bump and including: a conductive pattern formed between the outermost layer of the multi-layer wiring section and one of the inner-layer of the multilayer wiring section; and an interlayer connection via hole formed on the one of the inner-layer so as to oppose the bump forming portion.

With the above configuration, the wire drawn from the bump forming portion includes a 2-channel conductor line of the conductive pattern on the outermost layer of the multi-layer wiring section and the interlayer connecting via holes formed just below the bump forming portion. Accordingly, even when the disconnection is generated in one of a portion between the bump forming portion and the conductive pattern and a portion between the bump forming portion and the via hole, the connection to the bump can be maintained by the other portion, thereby making it difficult to cause a failure of disconnection.

According to a third aspect of at least one embodiment of the present invention, there is provided a high-frequency circuit device comprising: a semiconductor chip provided with a high-frequency circuit; a multi-layer wiring section comprised of organic material and formed on the semiconductor chip, an outermost layer of the multi-layer wiring section formed with a bump forming portion; and a bump formed on the bump forming portion; wherein one of the inner-layers is formed with a via hole which opposes the bump forming portion; wherein the via hole is a non-penetrating via hole which does not extend to a surface of the semiconductor chip.

With the above configuration, the via hole drawn from the bump forming portion is the non-penetrating via hole not extending to one surface of the semiconductor chip, it is possible to reduce the force acting on the via hole (non-penetrating via hole) in an amplitude direction of the ultrasonic vibration, in comparison with the penetrating via hole extending up to one surface of the semiconductor chip, thereby further preventing the disconnection of the via hole.

According to a fourth aspect of at least one embodiment of the present invention, there is provided a radar comprising a substrate on which the above high-frequency circuit device is mounted.

According to the radar, it is possible to perform a reliable bonding process between the high-frequency circuit device and the substrate, to reduce the management cost for components in the manufacturing process, and to enhance the yield of the manufactured components, thereby further reducing the cost. In addition, it is also possible to provide a radar not damaging the reliability after mounting and to further reduce the size of the device.

### BRIEF DESCRIPTION OF THE DRAWINGS

The above objects and advantages of the present invention will become more apparent by describing in detail exemplary embodiments thereof with reference to the accompanying drawings, wherein:

FIG. 1(a) is a partially enlarged sectional view schematically illustrating a part of a known high-frequency circuit device;

FIG. 1(b) is a partially enlarged sectional view schematically illustrating a part of the high-frequency circuit device which has been mounted on an external substrate by an ultrasonic bonding method;

FIGS. 2(a) and 2(b) are diagrams schematically illustrating a configuration of a vehicle radar employing a high-frequency circuit device according to a first embodiment of the invention;

FIG. 3(a) is a partially enlarged sectional view schematically illustrating a part of the high-frequency circuit device according to the first embodiment of the invention;

FIG. 3(b) is a partially enlarged sectional view schematically illustrating a part of the high-frequency circuit device which has been mounted on an external substrate by an ultrasonic bonding method;

FIG. 4(a) is a partially enlarged sectional view schematically illustrating a part of the high-frequency circuit device according to a second embodiment of the invention;

FIG. 4(b) is a partially enlarged sectional view schematically illustrating a part of the high-frequency circuit device which has been mounted on an external substrate by an ultrasonic bonding method;

FIG. 5(a) is a partially enlarged sectional view schematically illustrating a part of the high-frequency circuit device according to a third embodiment of the invention;

FIG. 5(b) is a partially enlarged sectional view schematically illustrating a part of the high-frequency circuit device which has been mounted on an external substrate by an ultrasonic bonding method;

FIG. 6 is a partial plan view of the high-frequency circuit device according to the third embodiment as viewed from a bump forming surface thereof; and

FIG. 7 is a partially enlarged sectional view schematically illustrating a part of a high-frequency circuit device according to another embodiment.

### DETAILED DESCRIPTION OF THE EMBODIMENTS

Hereinafter, a high-frequency circuit device according to exemplary embodiments of the invention will be described with reference to the accompanying drawings. In the following embodiments, the high-frequency circuit device according to the invention is applied to a component of a vehicle radar.

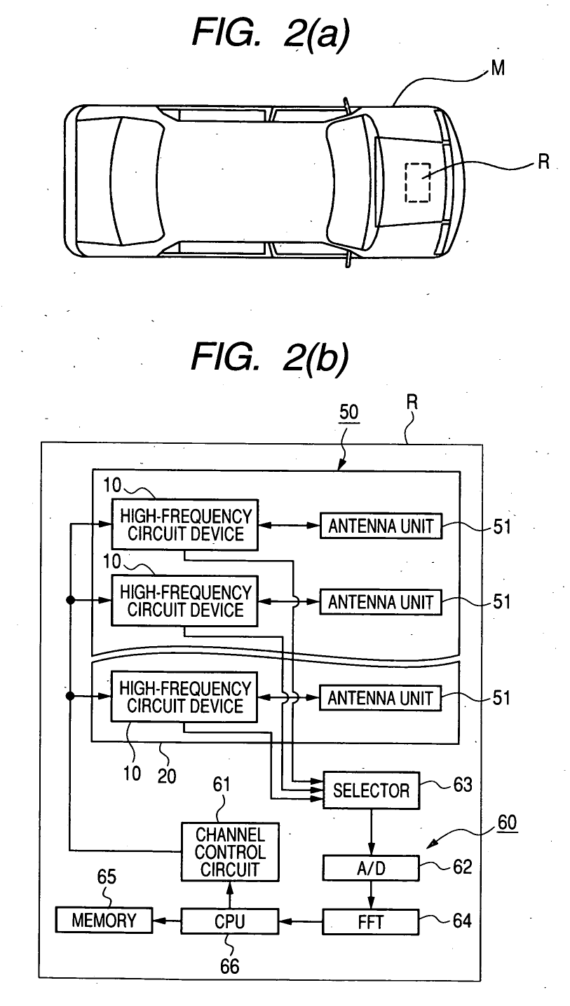

As shown in FIG. 2(a), a vehicle radar R is an apparatus that is mounted in the front portion of a vehicle M and that emits a millimeter-wave signal in the forward direction and measures a reflected wave from an object to detect a distance from the object or a relative speed to the object. Here, it will be described that the radar R is mounted in the front portion of the vehicle M, but the mounting position of the radar R is not limited to the front portion of the vehicle, but may be mounted in the rear portion of the vehicle so as to emit a millimeter-wave signal in the backward direction.

FIG. 2(b) is a block diagram schematically illustrating a part of the radar R. The radar R includes a transmitting and receiving module unit 50 and a main body 60. The transmitting and receiving module unit 50 includes plural high-frequency circuit devices 10 arranged on an external substrate 20 formed of a resin substrate and antennas 51 formed to correspond to the high-frequency circuit devices 10, respectively.

Each of the high-frequency circuit devices 10 includes a monolithic microwave integrated circuit (MMIC) having circuits constituting a communicator, an amplifier, a mixer, and a transceiver for switching transmission and reception of the millimeter-wave signal.

The main body 60 includes a channel control circuit 61 controlling transmitting and receiving channels, a selector 63 selecting a bit signal output from the high-frequency circuit device 1 and outputting the selected bit signal to an A/D converter 62, an FFT circuit 64 performing a fast Fourier transform on the digital bit signal converted by the A/D converter 62, a memory 65, and a CPU 66 controlling the units. The CPU 66 can calculate a distance to an object generating a reflected wave every receiving channel by analyzing the frequency spectrum of the received reflected signal input from the FFT circuit 64.

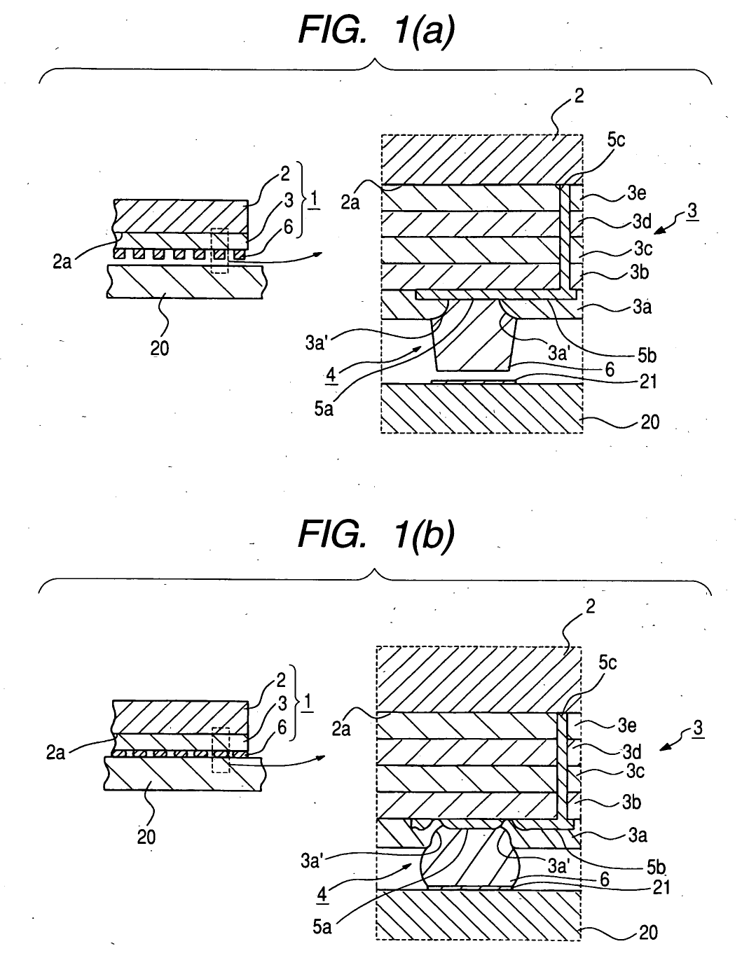

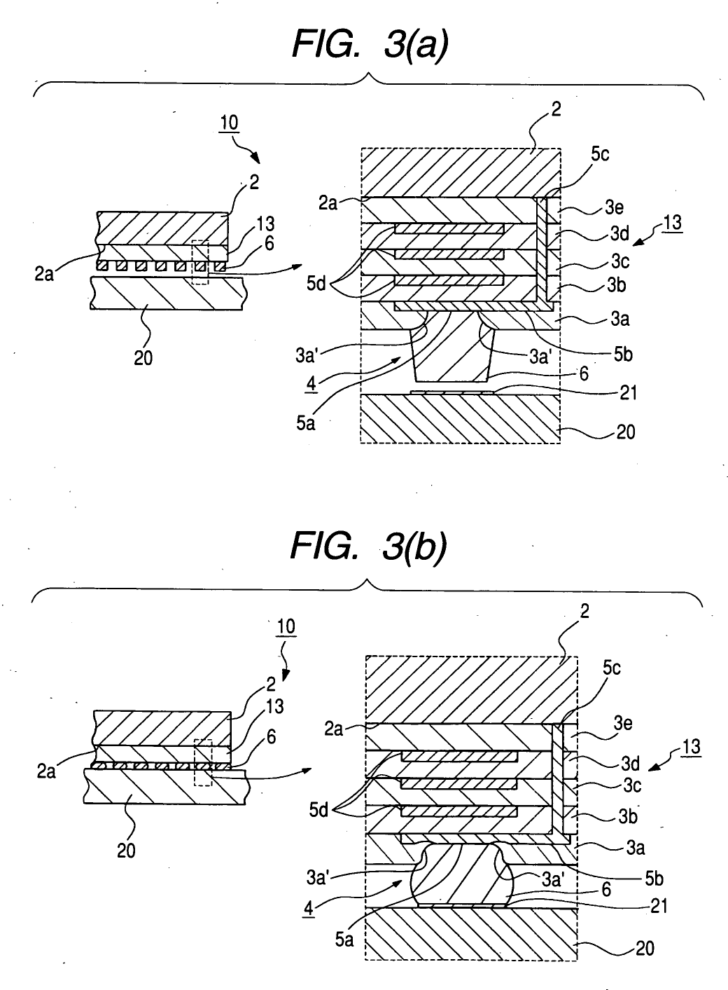

Next, a high-frequency circuit device 10 according to a first embodiment will be described. FIG. 3(a) is a partially enlarged sectional view schematically illustrating a part of the high-frequency circuit device according to the first embodiment of the invention and FIG. 3(b) is a partially enlarged sectional view schematically illustrating a part of the high-frequency circuit device 10 which has been mounted on an external substrate 20 by an ultrasonic bonding method. Elements having the same functions as the known high-frequency circuit device 1 shown in FIG. 1 are denoted by the same reference numerals and description thereof is omitted.

The high-frequency circuit device 10 includes an MMIC chip 2 having a substantially rectangular parallelepiped shape having horizontal and vertical lengths of about several millimeters, a multi-layer wiring section 13 formed on an electrode forming surface 2a of the MMIC chip 2, and a bump (gold bump) 6 formed in the outermost layer of the multi-layer wiring section 13.

The multi-layer wiring section 13 includes thin-film layers 3a to 3e stacked and formed out of a polyimide resin material, a bump forming portion 4 formed by exposing a bump base conductive layer 5a from the outermost thin-film layer 3a, a conductive pattern 5b drawn from the bump base conductive layer 5a of the bump forming portion 4, and a via hole 5c having one end connected to the conductive pattern 5b and the other end connected to an electrode of the MMIC chip 2. Further, reinforcing conductive layers 5d (reinforcing means) are formed at inner-layer positions, that is, on the thin-film layers 3c to 3e (on the bump 6 side), of the multi-layer wiring section 13 opposed to the bump forming portion 4.

The formation area of each of the reinforcing conductive layers 5d is preferably greater than the area of the bump 6 and the thickness of the each of the reinforcing conductive layers 5d may be equal to the thickness of another conductive pattern 5b or greater than the thickness of another conductive pattern 5b so as to enhance the degree of reinforcement. The bump base conductive layer 5a, the conductive pattern 5b, and the reinforcing conductive layers 5d are formed with about 2 μm by a gold plating method. Metal other than gold or a method other than the plating may be used.

The bump forming portion 4 is formed by coating a portion other than the bump forming portion 4 on the outermost layer (thin-film layer 3a) of the multi-layer wiring section 13 with a resist film and etching the bump forming portion 4 of the thin-film layer 3a with an etchant. Accordingly, in the bump forming portion 4 before being bonded to the external substrate 20, the end surface of the thin-film layer 3a is depressed in a rounded mortar shape and the bump 6 is formed to cover the depressed portion 3a′.

The diameter φ of the bump 6 is in the range of 40 to 50 μm and the height thereof is in the range of 20 to 30 μm, The diameter φ of the via hole 5c is in the range of several μm to 20 μm and preferably about 10 μm. About 200 bumps 6 are arranged on the outermost layer of the multi-layer wiring section 13.

In the figure, reference numeral 20 represents a resin substrate (referred to as external substrate) mounted with the high-frequency circuit device 10 and pads 21 to be bonded to the bumps 6 of the high-frequency circuit device 10 are formed at predetermined positions of the external substrate 20.

Next, a method of manufacturing the high-frequency circuit device 10 is described. The thin-film layers 3a to 3e made of a polyimide resin are stacked on the electrode forming surface 2a of the MMIC chip 2 having a high-frequency circuit formed thereon in the order from the MMIC chip 2. In the step of forming the thin-film layers, reinforcing conductive layers 5d are formed at positions opposed to the bump forming portions 4 by the gold plating method, openings are formed at a position where the via holes 5c are formed, the opening is filled with the plated gold to form the thin-film layer 3b, the bump base conductive layer 5a and the conductive pattern 5b are formed on the thin-film layer 3b by the gold plating method, and the thin-film layer 3a is formed thereon.

Thereafter, a resist film is formed on the thin-film layer 3a as the outermost layer and is subjected to an etching process. Then, a portion of the thin-film layer 3a of the bump forming portion 4 is removed to expose the bump base conductive layer 5a and the bump 6 is formed on the bump base conductive layer 5a. In this way, the high-frequency circuit device 10 is completed.

Next, a bonding state after the high-frequency circuit device 10 is mounted on the substrate 20 will be described. When the high-frequency circuit device 10 is mounted on the substrate 20, first, the high-frequency circuit device 10 is placed on the substrate 20 so that the bumps 6 of the high-frequency circuit device 10 are located on the pads 21 of the substrate 20. Thereafter, a weight and an ultrasonic vibration (60 Hz) set with a predetermined condition are applied from the upside of the high-frequency circuit device 10. Then, the bumps 6 are pressed and crushed to a certain height by means of the bonding to the pads 21 (see FIG. 3(b)).

At this time, a force pushing the depressed portion 3a′ of the thin-film layer 3a into the bump base conductive layer 5a of the bump forming portion 4 acts by means of the pressing force in the pressing direction of the bump 6. However, in the high-frequency circuit device 10, since the reinforcing conductive layers 5d are formed at the inner-layer position opposed to the bump forming portion 4 of the multi-layer wiring layer 13, the deformation of the thin-film layers 3b to 3e just below the bump 6 and the depressed portion 3a′ is hardly pushed into the bump base conductive layer 5a. As a result, the deforming force on the bonding portion of the bump forming portion 4 is suppressed, thereby hardly causing the disconnection in the bump base conductive layer 5a of the bump forming portion 4 or in the conductive pattern 5b drawn from the bump base conductive layer 5a.

In the high-frequency circuit device 10 according to the first embodiment, when the ultrasonic vibration is applied to the high-frequency circuit device to be bonded to the external substrate 20, the multi-layer section 3 is reinforced so as hardly to deform the bonding portion between the bump 6 and the bump forming portion 4. Specifically, the reinforcing conductive layer 5d is formed at the inner-layer position of the multi-layer wiring section 3 opposed to the bump forming portion 4. Accordingly, when the ultrasonic vibration is applied to the high-frequency circuit device to be bonded to the external substrate 20, it is possible to reduce the deformation of the bonding portion between the bump 6 and the bump forming portion 4, that is, to suppress the deformation phenomenon that the depressed portion 3a′ of the thin-film layer 3a is pushed into the bump base conductive layer 5a. It is also possible to further prevent the disconnection from being generated in the bump base conductive layer 5a of the bump forming portion 4 or the conductive pattern 5b drawn from the bump base conductive layer 5a.

Since the output level of the ultrasonic vibration can be set to perform an ultrasonic bonding process without markedly lowering the output level of the ultrasonic vibration, that is, so as to obtain a satisfactory bonding strength, it is possible to accomplish the strong bonding to the external substrate 20. Since it is also possible to lower the allowable level of the clearness of the bonding surface between the external substrate 20 and the high-frequency circuit device 10 or the required level of the plane precision, it is possible to reduce the management cost for components in the manufacturing process and to enhance the yield of the manufactured components, thereby enhancing the cost reducing effect. It is also possible to provide a device not damaging the reliability after mounting and to further reduce the size of the transmitting and receiving module unit 50 or the radar R.

In the high-frequency circuit device 10 according to the first embodiment, when the ultrasonic vibration is applied to the high-frequency circuit device to be bonded to the external substrate 20, the reinforcing conductive layer 5d is formed in the inner-layer position of the multi-layer wiring section 13 opposed to the bump forming portion 4 as the reinforcing means of the multi-layer wiring section 3 for suppressing the deformation of the bonding portion between the bump 6 and the bump forming portion 4. However, in another embodiment, instead of forming the reinforcing conductive layer 5d, the thin-film layers 3a to 3e may be formed of a material enhancing the hardness of the thin-film layers 3a to 3e (at least the thin-film layer 3a) of the multi-layer wiring section 13, that is, a material in which an inorganic material (inorganic filler such as silica or alumina) is mixed into the organic material (for example, polyimide resin material), thereby forming a layer structure in which fine particles of the inorganic material are uniformly dispersed in the thin film.

According to this structure, the hardness of the thin-film layers 3a to 3e can be enhanced. Accordingly, even when the force for pushing the depressed portion 3a′ of the thin-film layer 3a into the bump base conductive layer 5a of the bump forming portion 4 acts by means of the pressing force in the pushing direction of the bump 6 at the time of performing the ultrasonic bonding process, the deformation of the thin-film layer 3a is hardly caused due to its high hardness. As a result, since the depressed portion 3a′ is hardly pushed into the bump base conductive layer 5a, it is possible to obtain substantially the same advantage as the high-frequency circuit device 10.

In another embodiment, the thin-film layers 3a to 3e (at least the thin-film layer 3a) of the multi-layer wiring section 13 may be formed of a material including a thermosetting material such as an epoxy resin. Accordingly, since the hardness of the thin-film layers 3a to 3e can be enhanced higher than that of the thin-film layer made of polyimide, it is possible to obtain substantially the same advantage as the high-frequency circuit device 10 as described above.

In another embodiment, like the high-frequency circuit device 10, the reinforcing conductive layer 5d may be formed at the inner-layer position of the multi-layer wiring section 13 opposed to the bump forming portion 4 and the thin-film layers 3a to 3e (at least the thin-film layer 3a) of the multi-layer wiring section 13 may be formed of a material in which the inorganic material (inorganic filler such as silica or alumna) is mixed into the organic material or may be formed of a material including the thermosetting material as the organic material. According to this configuration, it is possible to further enhance the reinforcing effect of the multi-layer wiring section 13.

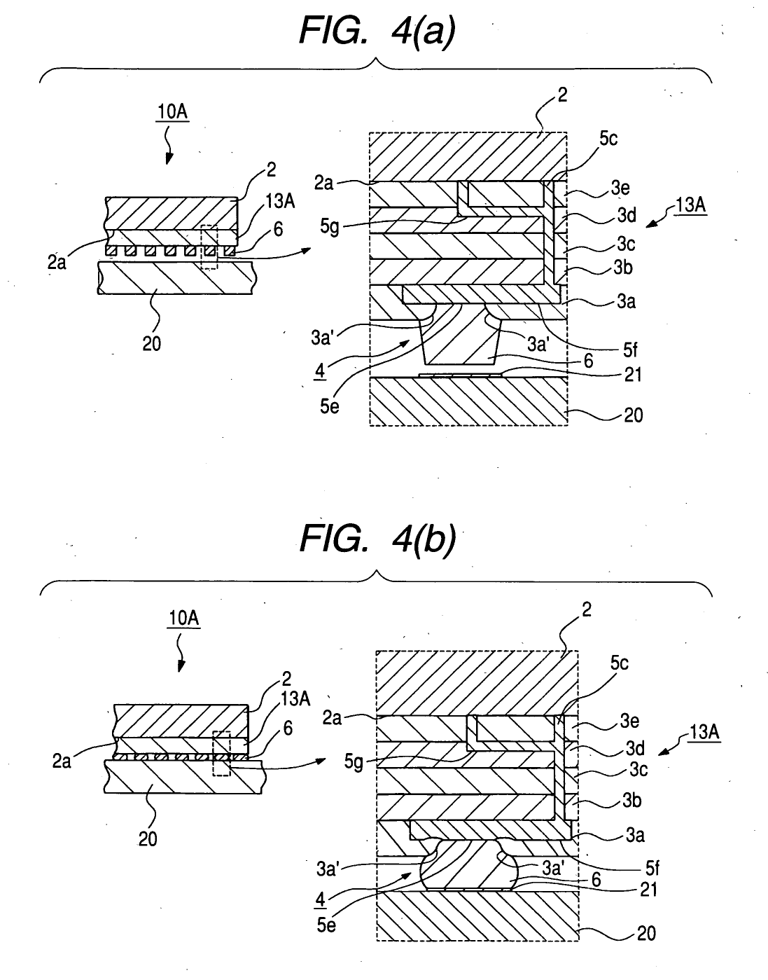

Next, a high-frequency circuit device according to a second embodiment of the invention will be described. FIG. 4(a) is a partially enlarged sectional view schematically illustrating a part of the high-frequency circuit device according to a second embodiment of the invention and FIG. 4(b) is a partially enlarged sectional view schematically illustrating a part of the high-frequency circuit device which has been mounted on an external substrate by an ultrasonic bonding method. Elements having the same functions as the high-frequency circuit device 10 shown in FIG. 3 are represented by the same reference numerals and description thereof is omitted.

In the high-frequency circuit device 10 according to the first embodiment, when the ultrasonic vibration is applied to the high-frequency circuit device to be bonded to the external substrate 20, the reinforcing conductive layer 5d is formed at the inner-layer position of the multi-layer wiring section 13 opposed to the bump forming portion 4 so as hardly to cause the deformation of the bonding portion between the bump 6 and the bump forming portion 4. On the contrary, in the high-frequency circuit device 10A according to the second embodiment, when the ultrasonic vibration is applied to the high-frequency circuit device to be bonded to the external substrate 20, the thickness of the bump base conductive layer 5e constituting the bump forming portion 4 is greater that of the other conductive patterns formed in the inner layer of the multi-layer wiring section 13A so as hardly to cause the deformation of the bonding portion between the bump 6 and the bump forming portion 4.

The high-frequency circuit device 10A includes an MMIC chip 2, a multi-layer wiring section 13A formed on an electrode forming surface 2a of the MMIC chip 2, and a bump (gold bump) 6 formed in the outermost layer of the multi-layer wiring section 13A.

The multi-layer wiring section 13A includes thin-film layers 3a to 3e stacked and formed out of a polyimide resin material, a bump forming portion 4 formed by exposing a bump base conductive layer 5e from the outermost thin-film layer 3a, a conductive pattern 5f drawn from the bump base conductive layer 5e of the bump forming portion 4, and a via hole 5c having one end connected to the conductive pattern 5f and the other end connected to an electrode of the MMIC chip 2.

The thicknesses of the bump base conductive layer 5e and the conductive pattern 5f constituting the bump forming portion 4 are greater by 1.5 to 2 times than the conductive pattern 5g formed in the inner layer of the multi-layer wiring section 13A. The bump base conductive layer 5e, the conductive pattern 5f, the penetrating via hole 5c, and the conductive pattern 5g can be formed, for example, by a gold plating method. A different metal or a different method may be used.

Next, a method of manufacturing the high-frequency circuit device 10A is described. The thin-film layers 3a to 3e made of a polyimide resin are stacked on the electrode forming surface 2a of the MMIC chip 2 having a high-frequency circuit formed thereon sequentially from the MMIC chip 2. In the step of forming the thin-film layers, the conductive patterns 5g in the inner layers are formed by the gold plating method, openings are formed at a position where the via holes 5c are formed, the openings are filled with the plated gold to form the thin-film layer 3b, the bump base conductive layer 5e and the conductive pattern 5f are formed on the thin-film layer 3b by the gold plating method so as to be thicker than the conductive patterns 5g in the inner layers, and the thin-film layer 3a is formed thereon.

Thereafter, a resist film is formed on the thin-film layer 3a as the outermost layer and is subjected to an etching process. Then, a portion of the thin-film layer 3a of the bump forming portion 4 is removed to expose the bump base conductive layer 5e and the bump 6 is formed on the bump base conductive layer 5e. In this way, the high-frequency circuit device 10A is completed.

Next, a bonding state after the high-frequency circuit device 10A is mounted on the substrate 20 will be described. When the high-frequency circuit device 10A is mounted on the substrate 20, first, the high-frequency circuit device 10A is placed on the substrate 20 so that the bumps 6 of the high-frequency circuit device 10A are located on the pads 21 of the substrate 20. Thereafter, a weight and an ultrasonic vibration set with a predetermined condition are applied from the upside of the high-frequency circuit device 10A. Then, the bumps 6 are pressed and crushed to a certain height by means of the bonding to the pads 21 (see FIG. 4(b)).

At this time, a force pushing the depressed portion 3a′ of the thin-film layer 3a into the bump base conductive layer 5e of the bump forming portion 4 acts by means of the pressing force in the pressing direction of the bump 6. However, in the high-frequency circuit device 10A, since the bump base conductive layer 5e and the conductive pattern 5f are thicker by 1.5 to 2 times than the conductive pattern 5g in the inner layers, the bump base conductive layer 5e or the conductive pattern 5f around the depressed portion 3a′ is hardly deformed and the depressed portion 3a′ is hardly pushed into the bump base conductive layer 5e. As a result, the deformation of the bonding portion of the bump forming portion 4 is suppressed, thereby hardly causing the disconnection in the bump base conductive layer 5e of the bump forming portion 4 or in the conductive pattern 5f drawn from the bump base conductive layer 5e.

In the high-frequency circuit device 10A according to the second embodiment, the thickness of the bump base conductive layer 5e constituting the bump forming portion 4 or the conductive pattern 5f drawn from the bump base conductive layer 5e is greater by 1.5 to 2 times than the conductive pattern 5g formed in the inner layer of the multi-layer wiring section 13A. Accordingly, when the ultrasonic vibration is applied to the high-frequency circuit device to be bonded to the external substrate 20, the deformation of the bonding portion between the bump 6 and the bump forming portion 4 can be suppressed. That is, the depressed portion 3a′ of the thin-film layer 3a can be prevented from the deformation that it is pushed into the bump base conductive layer 5e. Accordingly, it is possible to further prevent the phenomenon that the disconnection is generated in the conductive pattern 5f drawn from the bump base conductive layer 5e of the bump forming portion 4.

In the high-frequency circuit device 10A according to the second embodiment, the bump base conductive layer 5e constituting the bump forming portion 4 and the conductive pattern 5f drawn from the bump base conductive layer 5e are thicker than the conductive pattern 5g formed in the inner layer of the multi-layer wiring section 13A. However, in another embodiment, instead of simply making the thickness of the bump base conductive layer or the conductive pattern drawn from the bump base conductive layer greater, a conductive layer (that is, a barrier metal layer) made of a metal material (such as Ni, Ti, and W) having higher hardness than that of the bump base conductive layer or the conductive pattern may be formed on the bump base conductive layer constituting the bump forming portion 4 or the conductive pattern (pattern of the plated gold) drawn from the bump base conductive layer. From this structure, the same advantage as the high-frequency circuit device 10A can be obtained.

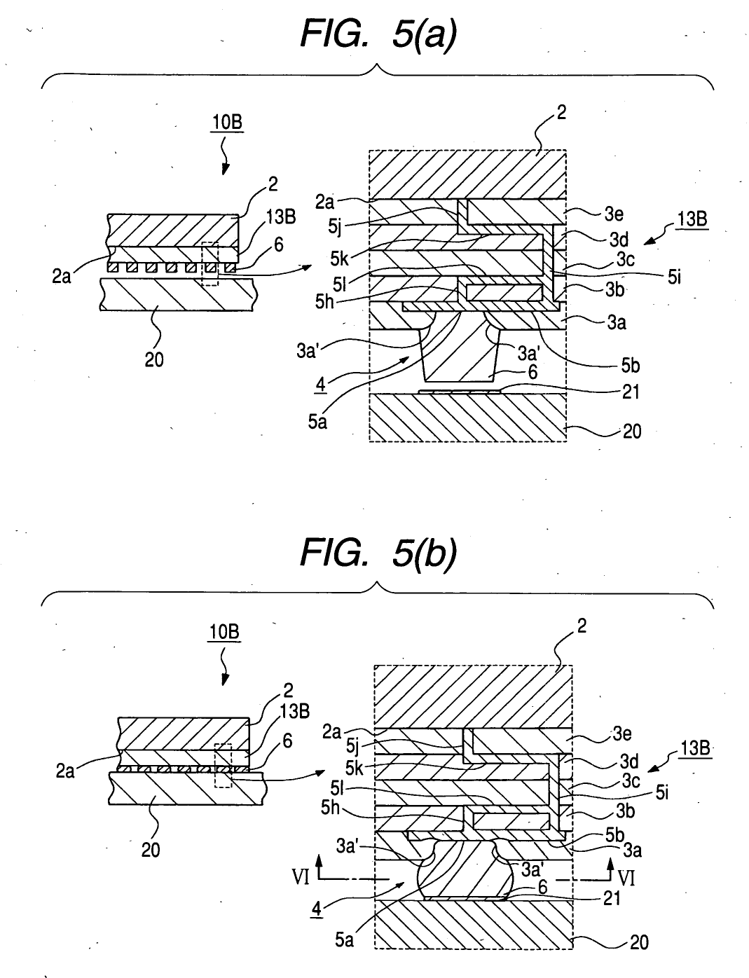

Next, a high-frequency circuit device according to a third embodiment of the invention will be described. FIG. 5(a) is a partially enlarged sectional view schematically illustrating a part of the high-frequency circuit device according to a third embodiment of the invention and FIG. 5(b) is a partially enlarged sectional view schematically illustrating a part of the high-frequency circuit device which has been mounted on an external substrate by an ultrasonic bonding method. Elements having the same functions as the high-frequency circuit device 10 shown in FIG. 3 are represented by the same reference numerals and description thereof is omitted.

In the high-frequency circuit device 10 according to the first embodiment, the wire drawn from the bump base conductive layer 5a of the bump forming portion 4 includes only the conductive pattern 5b. However, in the high-frequency circuit device 10B according to the third embodiment, the wire drawn from the bump base conductive layer 5a of the bump forming portion 4 includes the conductive pattern 5b formed in the outermost layer and a via hole 5h formed in the thin-film layer 3b from just below the bump forming portion 4 and the extending direction of the conductive pattern 5b is set substantially perpendicular to the direction of the ultrasonic vibration applied at the time of bonding to the external substrate 20.

The high-frequency circuit device 10B includes an MMIC chip 2, a multi-layer wiring section 13B formed on an electrode forming surface 2a of the MMIC chip 2, and a bump (gold bump) 6 formed in the outermost layer of the multi-layer wiring section 13B.

The multi-layer wiring section 13B includes thin-film layers 3a to 3e stacked and formed out of a polyimide resin material, a bump forming portion 4 formed by exposing a bump base conductive layer 5a from the outermost thin-film layer 3a, a conductive pattern 5b drawn from the bump base conductive layer 5a of the bump forming portion 4, a via hole 5i having one end connected to the conductive pattern 5b and penetrating the thin-film layers 3b to 3d, a via hole 5j penetrating the thin-film layer 3e, a conductive pattern 5k connected to the via hole 5i and the via hole 5j on the thin-film layer 3e, a via hole 5h penetrating the thin-film layer 3b from the bump base conductive layer 5a just below the bump forming portion 4, and a conductive pattern 5l connecting the via hole 5h and the via hole 5i on the thin-film layer 3c.

The bump base conductive layer 5a, the conductive patterns 5b, 5l, and 5k, and the via holes 5i, 5h, and 5j can be formed by the gold plating method. A different metal or a different method may be used.

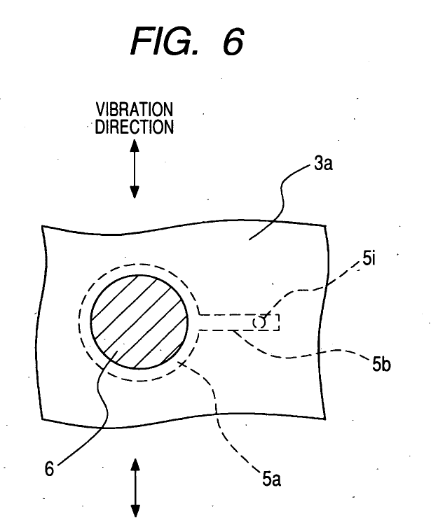

As can be seen from the partial plan view as viewed from the forming surface of the bump 6 in FIG. 6, the extending direction of the conductive pattern 5b in the outermost layer of the multi-layer wiring section 13B drawn from the bump forming portion 4 is set substantially perpendicular to the direction of the ultrasonic vibration indicated by an arrow in the figure.

Next, a method of manufacturing the high-frequency circuit device 10B is described. The thin-film layers 3b to 3e made of a polyimide resin are stacked on the electrode forming surface 2a of the MMIC chip 2 sequentially from the MMIC chip 2. In the step of forming the thin-film layers, openings are formed at positions where the via holes 5i, 5h, and 5j are formed, the openings are filled with the plated gold and the conductive patterns 5l and 5k are formed by the gold plating method to form the thin-film layer 3b, the bump base conductive layer 5a and the conductive pattern 5b are formed on the thin-film layer 3b by the gold plating method, and the thin-film layer 3a is formed thereon.

Thereafter, a resist film is formed on the thin-film layer 3a as the outermost layer and is subjected to an etching process. Then, a portion of the thin-film layer 3a of the bump forming portion 4 is removed to expose the bump base conductive layer 6a and the bump 6 is formed on the bump base conductive layer 5a. In this way, the high-frequency circuit device 10B is completed.

Next, a bonding state after the high-frequency circuit device 10B is mounted on the substrate 20 will be described. When the high-frequency circuit device 10B is mounted on the substrate 20, first, the high-frequency circuit device 10B is placed on the substrate 20 so that the bumps 6 of the high-frequency circuit device 10B are located on the pads 21 of the substrate 20. Thereafter, a weight and an ultrasonic vibration set with a predetermined condition are applied from the upside of the high-frequency circuit device 10B. Then, the bumps 6 are pressed and crushed to a certain height by means of the bonding to the pads 21 (see FIG. 5(b)).

At this timer a force pushing the depressed portion 3a′ of the thin-film layer 3a into the bump base conductive layer 5a of the bump forming portion 4 acts by means of the pressing force in the pressing direction of the bump 6. However, in the high-frequency circuit device 10B, since the direction of the conductive pattern 5b drawn from the bump base conductive layer 5a is set to substantially perpendicular to the direction of the ultrasonic vibration (see FIG. 6), the deformation of the bonding portion between the bump base conductive layer 5a and the conductive pattern 5b around the depressed portion 3a′ is suppressed and the depressed portion 3a′ is hardly pushed into the bump base conductive layer 5a. As a result, the disconnection is hardly generated in the conductive pattern 5b drawn from the bump base conductive layer 5a of the bump forming portion 4.

Since the via hole 5h drawn from the bump base conductive layer 5a is a via hole (non-penetrating via hole) penetrating only the thin-film layer 3b, the force acting in the amplitude direction of the ultrasonic vibration can be dispersed in the thin-film layers 3c to 3e thereon. Accordingly, the disconnection is hardly generated between the bump base conductive layer 5a and the via hole 5h.

In the high-frequency circuit device 10B according to the third embodiment, the wire drawn from the bump forming portion 4 is a 2-channel conductor line including the conductive pattern 5b and the via hole 5h. Accordingly, even when the disconnection is generated in one of a portion between the bump base conductive layer 5a and the conductive pattern 5b and a portion between the bump base conductive layer 5a and the via hole 5h, the connection to the bump 6 can be maintained by the other portion, thereby hardly causing the defective disconnection.

Since the direction of the conductive pattern 5b of the multi-layer wiring section 13B drawn from the bump base conductive layer 5a of the bump forming portion 4 is set substantially perpendicular to the direction of the ultrasonic vibration applied at the time of bonding to the external substrate 20, the stress applied between the bump base conductive layer 5a and the conductive pattern 5b can be reduced by disposing the conductive pattern 5b at a position to which the stress resulting from the ultrasonic vibration is hardly applied, thereby further preventing the disconnection.

By constructing the via hole 5h drawn from the bump base conductive layer 5a of the bump forming portion 4 by the use of the non-penetrating via hole not extending from the bump base conductive layer 5a to the MMIC chip 2, it is possible to reduce the force acting on the via hole 5h in the direction of the ultrasonic vibration, in comparison with the penetrating via hole extending to the MMIC chip 2, thereby further preventing the disconnection of the via hole 5h.

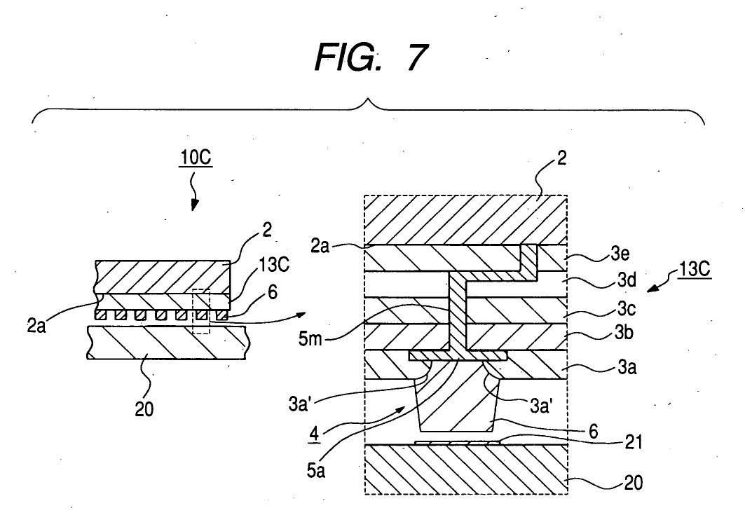

In the high-frequency circuit device 10B according to the third embodiment, the wire drawn from the bump base conductive layer 5a of the bump forming portion 4 is divided into the 2-channel conductor lines of the conductive pattern 5b in the outermost layer of the multi-layer willing section 13B and the via hole 5h formed in the thin-film layer 13b of the multi-layer willing section 13B. However, in a high-frequency circuit device 10C according to another embodiment of the invention, as shown in FIG. 7, the wire drawn from the bump base conductive layer 5a of the bump forming portion 4 may include a 1-channel via hole 5m extending from a portion just below the bump base conductive layer 5a but not extending to the thin-film layer 3e formed on the electrode forming surface of the MMIC chip 2. In this configuration, since the via hole 5m does not extend to the thin-film layer 3e, it is possible to reduce the force acting in the direction of the ultrasonic vibration, in comparison with the penetrating via hole extending to the TIC chip 2, thereby further preventing the disconnection of the via hole 5m.

the features of the high-frequency circuit devices according to the first to third embodiments and the high-frequency circuit devices according to the above-mentioned other embodiments may be combined. According to these combinations, it is possible to further enhance the advantages.

Although it has been described in the first to third embodiments that the multi-layer wiring sections 13, 13A, and 13B include 5 thin-film layers 3a to 3e, the number of thin-film layers of the multi-layer willing section may be 4 or less, or may be 6 or more. The thin-film layers may be made of an organic material other than polyimide.

Although the present invention has been shown and described with reference to specific preferred embodiments, various changes and modifications will be apparent to those skilled in the art from the teachings herein. Such changes and modifications as are obvious are deemed to come within the spirit, scope and contemplation of the invention as defined in the appended claims.

What is claimed is:

1. A high-frequency circuit device comprising:
a semiconductor chip provided with a high-frequency circuit;
a multi-layer wiring section comprised of organic material and formed on the semiconductor chip, an outermost layer of the multi-layer wiring section formed with a bump forming portion; and
a bump formed on the bump forming portion;
wherein the multi-layer wiring section is provided with a reinforcing means for suppressing a deformation of a bonding portion between the bump and the bump forming portion when the high-frequency circuit device is bonded to a substrate with an ultrasonic vibration applied thereto.

2. The high-frequency circuit device as set forth in claim 1, wherein the reinforcing means includes a reinforcing conductive layer formed on at least one of inner-layers of the multi-layer wiring section so as to oppose the bump forming portion.

3. The high-frequency circuit device as set forth in claim 1,
wherein the reinforcing means includes an insulating layer of the outermost layer; and
the insulating layer is comprised of material in which inorganic material is mixed into organic material.

4. The high-frequency circuit device as set forth in claim 1,
wherein the reinforcing means includes an insulating layer of the outermost layer; and
the insulating layer is comprised of thermosetting material as the organic material.

5. The high-frequency circuit device as set forth in claim 1,
wherein the reinforcing means includes a bump base conductive layer formed between one of inner-layers of the multi-layer wiring section and the bump; and
wherein a thickness of the bump base conductive layer is greater than a thickness of a conductive pattern formed between the inner-layers.

6. The high-frequency circuit device as set forth in claim 1,
wherein the reinforcing means includes a conductive layer formed on a bump base conductive layer formed between one of inner-layers of the multi-layer wiring section and the bump; and
wherein a hardness of the conductive layer is greater than a hardness of the bump base conductive layer.

7. A high-frequency circuit device comprising:
a semiconductor chip provided with a high-frequency circuit;
a multi-layer wiring section comprised of organic material and formed on the semiconductor chip, an outermost layer of the multi-layer wiring section formed with a bump forming portion;
a bump formed on the bump forming portion; and
a wire electrically connecting the semiconductor chip with the bump and including:
a conductive pattern formed between the outermost layer of the multi-layer wiring section and one of the inner-layer of the multilayer wiring section; and
an interlayer connection via hole formed on the one of the inner-layer so as to oppose the bump forming portion.

8. The high-frequency circuit device as set forth in claim 7, wherein an extending direction of the conductive pattern is substantially perpendicular to a vibration direction of an ultrasonic vibration applied when the high-frequency circuit device is bonded to a substrate.

9. A high-frequency circuit device comprising:
a semiconductor chip provided with a high-frequency circuit;
a multi-layer wiring section comprised of organic material and formed on the semiconductor chip, an outermost layer of the multi-layer wiring section formed with a bump forming portion; and
a bump formed on the bump forming portion;
wherein one of the inner-layers is formed with a via hole which opposes the bump forming portion;
wherein the via hole is a non-penetrating via hole which does not extend to a surface of the semiconductor chip.

10. A radar comprising a substrate on which the high-frequency circuit device as set forth in claim 1 is mounted.

11. A radar comprising a substrate on which the high-frequency circuit device as set forth in claim 7 is mounted.

12. A radar comprising a substrate on which the high-frequency circuit device as set forth in claim 9 is mounted.
